(19) United States
(12) Patent Application Publication
(10) Pub. No.: US 2010/0078726 A1
(43) Pub. Date: Apr. 1, 2010

(54) SEMICONDUCTOR DEVICE

(75) Inventor: HOMARE SATO, TOKYO (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/571,543

(22) Filed: Oct. 1, 2009

(30) Foreign Application Priority Data
Oct. 1, 2008 (JP) 2008-256287

(51) Int. Cl. H01L 27/088

(52) U.S. Cl. 257/368; 257/E27.06

(57) ABSTRACT

A semiconductor device includes a first semiconductor diffusion region of a first transistor, a second semiconductor diffusion region of a second transistor, and a third semiconductor diffusion region that connects the first and second semiconductor diffusion regions to each other.

### BACKGROUND OF THE INVENTION

1. Field of the Invention

The present invention relates to a semiconductor device.

Priority is claimed on Japanese Patent Application No. 2008-256287 filed on Oct. 1, 2008, the contents of which are incorporated herein by reference.

2. Description of Related Art

In a semiconductor device with transistors and wirings, desired logical functions and storage functions are obtainable by changing the layout of the wirings which connect the transistors. In other words, the transistors may be n-channel MOSFETs (Metal Oxide Semiconductor Field Effect Transistors) and p-channel MOSFETs. The n-channel MOSFET and the p-channel MOSFET are laid-out in a chip, and input and output terminals thereof are connected to each other through the wirings.

The Japanese Unexamined Patent Publication, First Publication No. H07-153926 discloses an example of the aforementioned semiconductor device in which n-channel MOSFETs, p-channel MOSFETs and wirings are laid out. This Publication also discloses a semiconductor device which has a gate electrode, a source region, and a drain region, which are arranged in a chip. In the semiconductor device, the gate electrode, the source region and the drain region are electrically connected to each other.

However, for the semiconductor device disclosed in the above-described Publication, voltage and signal are supplied via voltage lines and signal lines to the gate electrode, the source region, and the drain region. Therefore, for example, it is necessary to provide the semiconductor device with sub-lines which are branched from the signal line. The sub-lines are used to transmit signals to a plurality of gate electrodes of the n-channel MOSFETs or p-channel MOSFETs. It is necessary to provide the sub-lines outside the region in which the transistors such as the n-channel MOSFET and the p-channel MOSFET are formed. This lay-out of the sub-lines outside the transistor region increases the wiring area of a chip, wherein the wiring area is necessary for providing the wirings in the chip.

### SUMMARY

According to one embodiment, a semiconductor device includes a first semiconductor diffusion region of a first transistor, a second semiconductor diffusion region of a second transistor, and a third semiconductor diffusion region that connects the first and second semiconductor diffusion regions to each other.

According to another embodiment, a semiconductor device includes a first transistor having a first gate, a first source and a first drain; a second transistor having a second gate, a second source and a second drain; and a diffusion region that connects one of the first source and the first drain to one of the second source and the second drain.

According to still another embodiment, a semiconductor device includes a first transistor; a second transistor; and a semiconductor diffusion region extends between the first and second transistors, the semiconductor diffusion region extends to reach both one of source and drain regions of the first transistor and one of source and drain regions of the second transistor.

### BRIEF DESCRIPTION OF THE DRAWINGS

FIG. 1A and FIG. 1B are plan views showing a semiconductor device according to a first embodiment of the present invention.

FIG. 2 is a circuit diagram of a semiconductor device according to a second embodiment of the present invention.

FIG. 3A and FIG. 3B are plan views showing the semiconductor device according to the second embodiment of the present invention.

FIG. 4 is a circuit diagram of a semiconductor device according to a third embodiment of the present invention.

FIG. 5A and FIG. 5B are plan views showing the semiconductor device according to the third embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

The following are descriptions of a semiconductor device with reference to the drawings according to an embodiment of the present invention. In some drawings according to the embodiment, features are enlarged for easily understanding, and size and ratio of each configuration may be different from the real one. While an embodiment of the present invention is described below, the specific configuration thereof is not limited to the embodiment. Designs and the like (for example, material, scale) which do not depart from the spirit or scope of this invention are also included.

### First Embodiment

In the first embodiment, for example, the present invention relates to a semiconductor device using a p-channel MOSFET.

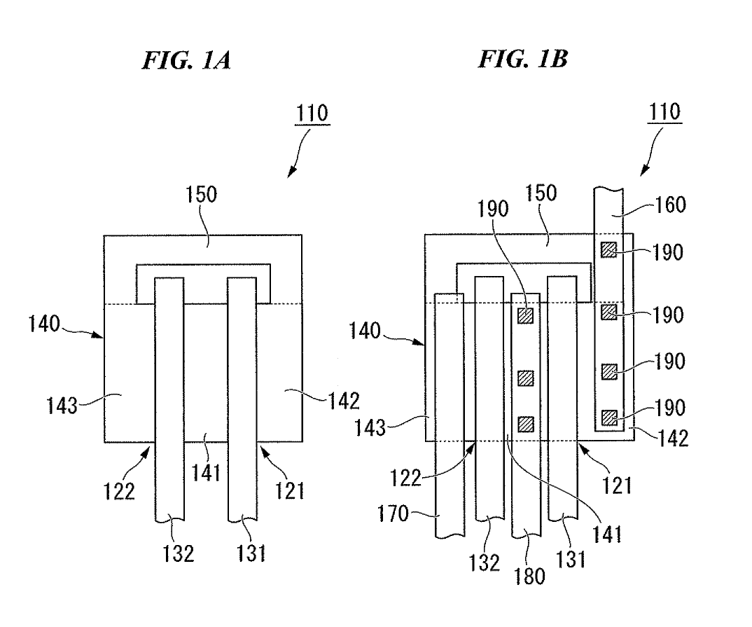

As shown in FIG. 1A, a semiconductor device 110 according to the embodiment schematically includes a p-type semiconductor region 140, a pair of gate wirings 131, 132, and a diffusion region 150. A pair of the gate wirings 131 is formed over the p-type semiconductor region 140. The diffusion region 150 is connected to the p-type semiconductor region 140. More specifically, the gate wirings 131 and 132 are provided in parallel with each other. A pair of the gate wirings 131 and 132 divides the p-type semiconductor region 140 into three impurity diffusion regions 141, 142 and 143.

The impurity diffusion region 141 is provided between a pair of the gate wirings 131 and 132. The impurity diffusion region 142 is provided at an opposite side of the impurity diffusion region 141 over the gate wiring 131. The impurity diffusion region 143 is provided at the opposite side of the impurity diffusion region 141 over the gate wiring 132.

The diffusion region 150 is provided to connect the impurity diffusion region 142 and the impurity diffusion region 143 to each other. In addition, the diffusion region 150 and the impurity diffusion region 141 are not connected to each other.

In the semiconductor device 110, the p-type semiconductor region 140 and a pair of the gate wirings 131 and 132 form two p-channel MOSFETs. More specifically, a semiconductor device 110 includes a first transistor 121 and a second transistor 122. The first transistor 121 uses the gate wiring 131 as the gate electrode, and uses the impurity diffusion regions 141 and 143 as the source region and the drain region. The second transistor 122 uses the gate wiring 132 as the gate electrode, and uses the impurity diffusion regions 141 and 143 as the source region and the drain region.

In a semiconductor device 110, the impurity diffusion region 142 and the impurity diffusion region 143 are connected to each other. The impurity diffusion region 142 is one of a source region or a drain region of the first transistor 121. The impurity diffusion region 143 is one of a source region or a drain region of the second transistor 122.

The impurity diffusion region 141 is used as both the source region and the drain region of the first transistor 121 and the second transistor 122 commonly.

For example, the gate wirings (the gate electrodes) 131 and 132 may be made of metal (for example, poly-silicon, W (tungsten), and Ti (titanium)) or of silicide.

For example, the p-type semiconductor layer 140 and the diffusion region 150 may be formed by injecting boron into a silicon substrate. A silicide layer may be formed on the surface of the p-type semiconductor layer 140 and the diffusion region 150 by using a silicide technology. Especially, if the silicide layer is formed on the diffusion region 150, it is possible to decrease the resistance value of the diffusion region 150.

As shown in FIG. 1B, the semiconductor device 110 may include a first wiring 160, a second wiring 170 and a third wiring 180. The first line 160 may be formed on the impurity diffusion region 142 which is one of a source region or a drain region of the first transistor 121. The second wiring 170 may be formed on the impurity diffusion region 143 which is one of a source region or a drain region of the second transistor 122. The third wiring 180 may be formed on the impurity diffusion region 141 which is used as the source region or the drain region of the first transistor 121 and the second transistor 122.

The first line 160 may be connected to one of an impurity diffusion region 142 and a diffusion region 150 which is used as one side of the source region or the drain region of the first transistor 121 and which is provided under the first wiring 160, via the contact 190.

The third wiring 180 may be connected to one of an impurity diffusion region 141 which is used as another side of the source region or a drain region of the second transistor 122 which is provided under the third wiring 180, via the contact 190.

The second wiring 170 is not connected to the impurity diffusion region 143 which is one of a source region or a drain region of the second transistor 122 which is provided under the second wiring 170. Therefore, the second wiring 170 is formed on the impurity diffusion region 143, via an insulator layer (not shown). The second wiring 170 is not connected to the impurity diffusion region 143, but is connected to the gate wiring 131 and 132 in the area which is not illustrated.

The impurity diffusion region 143 is different from the aforementioned impurity diffusion regions 141 and 142, a wiring which is connected to the impurity diffusion region 143 is not provided above the impurity diffusion region 143. In other words, the impurity diffusion region 143 is connected to the impurity diffusion region 142 by not a dedicated wiring but by the diffusion region 150, and is connected to the first wiring 160 via the contact 190.

According to the semiconductor device 110 of the first embodiment, if the first wiring 160 is connected to a supply wiring, the impurity diffusion region 142 which is connected to the first wiring 160 becomes the source region of the first transistor 121. In addition, the impurity diffusion region 143 which is connected to the first wiring 150 via the diffusion region 150 becomes the source region of the second transistor 122. In addition, the impurity diffusion region 141 becomes the drain region which is used by both the first transistor 121 and the second transistor 122.

By the way, if the diffusion region 150 is not provided, it is necessary to provide with wirings to connect the first line 160 to both the impurity diffusion regions 142 and 143 for applying the same electric potential to the impurity diffusion regions 142 and 143. In this case, as shown in FIG. 1B, if it is necessary to provide with the second wiring 170, the first wiring 160 is formed over the impurity diffusion region 143. Therefore, it is necessary that the second line 170 is provided at left side from the position shown in FIG. 1B. Therefore, the chip has the increased area in which the wirings are provided.

According to the first embodiment, the impurity diffusion region 142 and the impurity diffusion region 143 are connected by the diffusion region 150. Therefore, as shown in FIG. 1B, the second wiring 170 is provided over the impurity diffusion region 143, and it is possible to decrease the wiring-formation area of the chip, wherein the wirings are formed in the wiring-formation area.

For example, the first line 160, the second wiring 170, and the third wiring 180 may be made of one of copper, aluminum, and a metal having a high melting point, and may be formed by a general multi level interconnection technology.

In addition, the first wiring 160, the second wiring 170, and the third wiring 180 may be formed on the layer which is provided with the gate wirings 131 and 132.

According to the first embodiment of the present invention, the impurity diffusion region 142 which is one of a source region or a drain region of the first transistor 121, and the impurity diffusion region 143 which is one of a source region or a drain region of the second transistor 122, are connected to each other via the diffusion region 150. In addition, part of the diverted wirings for a voltage or a signal may include the diffusion region 150. Therefore, it is possible to omit the wirings for the impurity diffusion region 143, and it is possible to decrease the area of the chip in which the wirings are provided.

In addition, according to the semiconductor device 110 of the first embodiment, the first transistor 121 and the second transistor 122 share the impurity diffusion region 141 as one of source and drain. Therefore, it is possible to decrease the area which the transistor is provided. Therefore, it is possible to decrease the transistor area of the chip.

### Second Embodiment

Next, a second embodiment of the present invention is described.

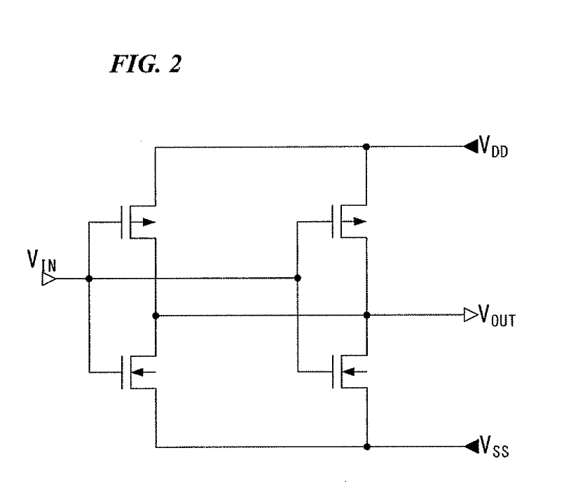

In the second embodiment, for example, the present invention relates to a semiconductor device which includes an inverter circuit shown in FIG. 2.

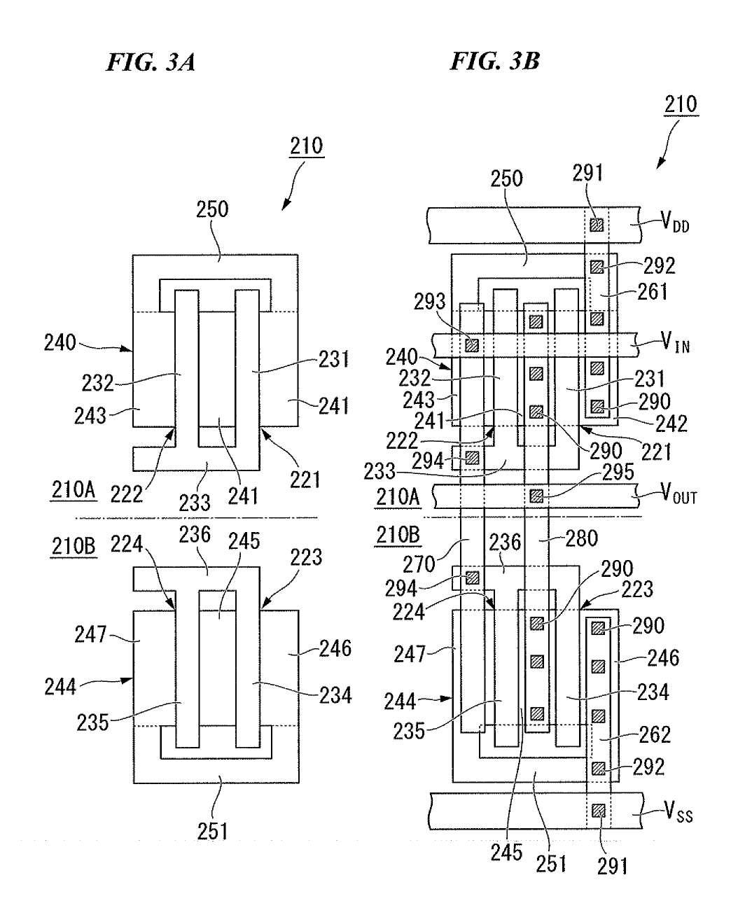

As shown in FIG. 3A, a semiconductor device 210 according to the second embodiment basically includes an N-well region 210A and a P-well region 210B. In addition, a p-type semiconductor region 240, a pair of gate wirings 231, 232 and a diffusion region 250 is provided in the N-well region 210A. A pair of gate wirings 231 and 232 which are formed on the p-type semiconductor region 240. The diffusion region 250 is connected to the p-type semiconductor region 240. More specifically, the gate wirings 231 and 232 are provided in parallel with each other. A pair of the gate wirings 231 and 232 divides the p-type semiconductor region 240 into three impurity diffusion regions 241, 242 and 243. In addition, one side edges of the gate wirings 231 and 232 are connected to the gate wiring 233. The gate wiring 233 is provided outside the p-type semiconductor region 240 and opposite to the diffusion region 250. The gate wiring 233 is formed along the direction which is orthogonal to the gate wirings 231 and 232.

On the other hand, an n-type semiconductor region 244, a pair of the gate wirings 234, 235, a diffusion region 251 may be provided in the P-well region 210B. A pair of the gate wirings is formed in the n-type semiconductor region 244. The diffusion region 251 is connected to the n-type semiconductor region 244. More specifically, the gate wirings 234 and 235 are provided in parallel with each other. A pair of the gate wirings 234 and 235 divides the n-type semiconductor region 244 into three impurity diffusion region 244, 246 and 247. In addition, one side edges of the gate wirings 234 and 235 are connected to the gate wiring 236. The gate line 236 is provided outside the n-type semiconductor region 244 and opposite to the diffusion region 251. The gate wiring 236 is formed along the direction which is orthogonal to the gate wirings 234 and 235.

The diffusion region 250 connects the impurity diffusion region 242 and the impurity diffusion region 243. On the other hand, the diffusion region 251 connects the impurity diffusion region 246 and impurity diffusion region 247. In addition, the diffusion region 250 and the impurity diffusion region 241 are not connected to each other. In addition, the diffusion region 251 and the impurity diffusion region 245 are not connected to each other.

Two p-channel MOSFETs are formed at the N-well region 210A by the p-type semiconductor region 240 and a pair of the gate wirings 231 and 232 which are formed on the p-type semiconductor region 240. More specifically, a semiconductor device 210 includes a first transistor 221 and a second transistor 222. The first transistor 221 uses the gate wiring 231 as the gate electrode, and uses the impurity diffusion regions 241 and 242 as the source region and the drain region. The second transistor 222 uses the gate wiring 232 as the gate electrode, and uses the impurity diffusion regions 241 and 243 as the source region and the drain region.

Two n-channel MOSFETs are formed at the P-well region 210B by the n-type semiconductor region 244 and a pair of the gate wirings 234 and 235 which are formed on the n-type semiconductor region 244. More specifically, a semiconductor device 210 includes a third transistor 223 and a fourth transistor 224. The third transistor 223 uses the gate wiring 234 as the gate electrode, and uses the impurity diffusion regions 245 and 246 as the source region and the drain region. The fourth transistor 224 uses the gate wiring 235 as the gate electrode, and uses the impurity diffusion regions 245 and 247 as the source region and the drain region.

In the semiconductor device 210, the impurity diffusion region 242 and the impurity diffusion region 243 are connected to each other by the diffusion region 250. The impurity diffusion region 242 is one of source and drain of the first transistor 221. The impurity diffusion region 243 is one of source and drain of the second transistor 222.

The impurity diffusion region 241 is used as both the source region and the drain region of the first transistor 221 and the second transistor 222.

In the semiconductor device 210, the impurity diffusion region 246 and the impurity diffusion region 247 are connected to each other by the diffusion region 251. The impurity diffusion region 246 is one of source and drain of the third transistor 223. The impurity diffusion region 247 is one of source and drain of the fourth transistor 224.

The impurity diffusion region 245 is used as both the source region and the drain region of the third transistor 223 and the fourth transistor 224.

For example, the p-type semiconductor layer 240 and the diffusion region 250 are formed by injecting boron into a silicon substrate. On the other hand, the n-type semiconductor layer 244 and the diffusion region 251 are formed by injecting phosphorus into the silicon substrate.

A silicide layer may be formed on the surface of the p-type semiconductor layer 240, the diffusion region 250, the n-type semiconductor layer 244 and the diffusion region 251 by using the salicide technology. Especially, if the silicide layer is formed on the diffusion regions 250 and 251, it is possible to decrease the resistance values of the diffusion regions 250 and 251.

In the semiconductor device 210 which includes the aforementioned basic configurations, as shown in FIG. 3B, plurality of wirings are laminated. More specifically, first wirings 261, 262, a second wiring 270, and a wiring 280 are laminated on a layer which is provided with the gate wirings 231 to 236. The first wiring 261 is formed above the impurity diffusion region 242. The first wiring 262 is formed above the impurity diffusion region 246. The second wiring 270 is formed above an area which is from the impurity diffusion region 243 to the impurity diffusion region 247. The wiring 280 is formed above an area which is from the impurity diffusion region 241 to the impurity diffusion region 245. In addition, the first wirings 261, 262, the second wiring 270 and the wiring 280 are provided along a direction which is parallel to the gate wirings 231, 232 and the gate wirings 234, 235.

An input wiring VIN (a third wiring), an output wiring VOUT, a supply wiring VD and a supply wiring VSS are laminated above the layer which is provided with the first wirings 261, 262, the second wiring 270 and the wiring 280, via another layer. In addition, the input wiring VIN, the output line VOUT, a supply wiring VD and a supply wiring VSS are provided along the direction which is parallel to the first wirings 261, 262, the second wiring 270 and the wiring 280.

The supply wiring VDD is connected to the first wiring 261 via the contact 291. In addition, the first wiring 261 is connected to the impurity diffusion region 242 which is the source region of the first transistor 221, via the contact 290. The first wiring 261 is connected to the impurity diffusion region 243 which is the source region of the second transistor 222, via the contact 290 and the diffusion region 250.

Likely, the supply wiring VSS is connected to the first wiring 262 via the contact 291. The first wiring 262 is connected to the impurity diffusion region 246 which is the source region of the third transistor 223, via the contact 290. In addition, the first wiring 262 is connected to the impurity diffusion region 247 which is the source region of the fourth transistor 224, via the contact 292 and the diffusion region 251.

The input wiring VIN (the third wiring) is provided over the first transistor 221, the second transistor 222 and the second wiring 270, and is connected to the second wiring 270 via the contact 293. In the N-well region 210A and the P-well region 210B, the second wiring 270 is connected to the gate wiring 233 and the gate wiring 236 via the contact 294.

The output wiring VOUT is provided on the line 280 and is connected to the wiring 280 via the contact 295. The wiring 280 is connected to the impurity diffusion region 241 and the impurity diffusion region 245 via the contact 290. The impurity diffusion region 241 is used as the drain region of the first transistor 221 or the second transistor 222. The impurity diffusion region 245 is used as the drain region of the third transistor 223 or the fourth transistor 224.

By the way, if the diffusion regions 250 and 251 are not provided, it is necessary to provide with wirings to connect the first wirings 261 to both the impurity diffusion regions 242 and 243 for applying the same electric potential to the impurity regions 242 and 243, and it is necessary to provide with wirings to connect the first wiring 262 to both the impurity diffusion regions 246 and 247 for applying the same electric potential to the impurity diffusion regions 246 and 247. In this case, as shown in FIG. 3B, if it is necessary to provide the second wiring 270, the first wirings 261 and 262 are formed over the impurity diffusion regions 243 and 247. Therefore, it is necessary that the second wiring 270 is provided at left side from the position shown in FIG. 3B. Therefore, an area of the chip in which the wirings are provided increase.

According to the second embodiment, the impurity diffusion regions 242 and 243 are connected by the diffusion region 250, and the impurity diffusion regions 246 and 247 are connected by the diffusion region 251. Therefore, as shown in FIG. 3B, the second line 270 is provided over the impurity diffusion regions 243 and 247, and it is possible to decrease an area of the chip in which wirings are provided.

For example, the first wirings 261 and 262, the second wiring 270, the wiring 280, the input wirings VIN (the third wiring), the output wiring VOUT, the supply wiring VDD and the supply wiring VSS made of one of copper, aluminium, and a metal having a high melting point, and are formed by a general multi level interconnection technology.

According to the semiconductor device 210 of the second embodiment, plurality of transistors and plurality of wirings are provided as shown in FIG. 3A and FIG. 3B. Therefore, it is possible to form the inverter circuit shown in the FIG. 2 easily.

In addition, according to the semiconductor device 210 of the second embodiment, the diffusion regions 251 and 252 are provided at the N-well region 210A and the P-well region 210B. Therefore, similar to the semiconductor device 110 according to the first embodiment, it is possible to omit wirings for the impurity diffusion regions 243 and 247. Therefore, it is possible to form the second wiring 270 above the impurity diffusion regions 243 and 247, and it is possible to decrease an area which the wirings are provided.

In addition, the second wiring 270 is provided above the impurity diffusion regions 243 and 247. Therefore, it is possible to freely select the connection point of the input wiring VIN (the third wiring) which is connected to the second wiring 270. Therefore, it is possible to increase degree of design freedom for the wiring.

### Third Embodiment

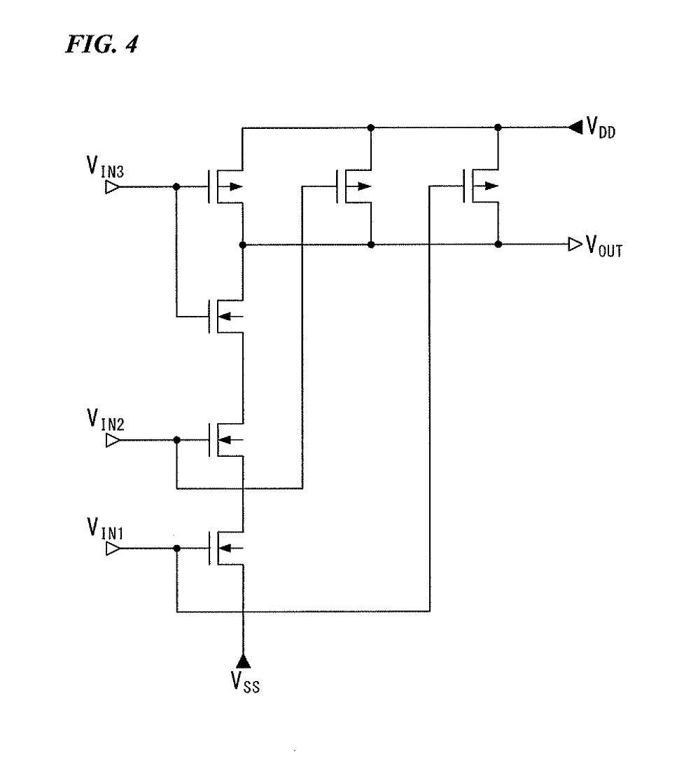

Next, a third embodiment of the present invention is described. In the third embodiment, for example, the present invention relates to a semiconductor device which includes an NAND gate shown in FIG. 4.

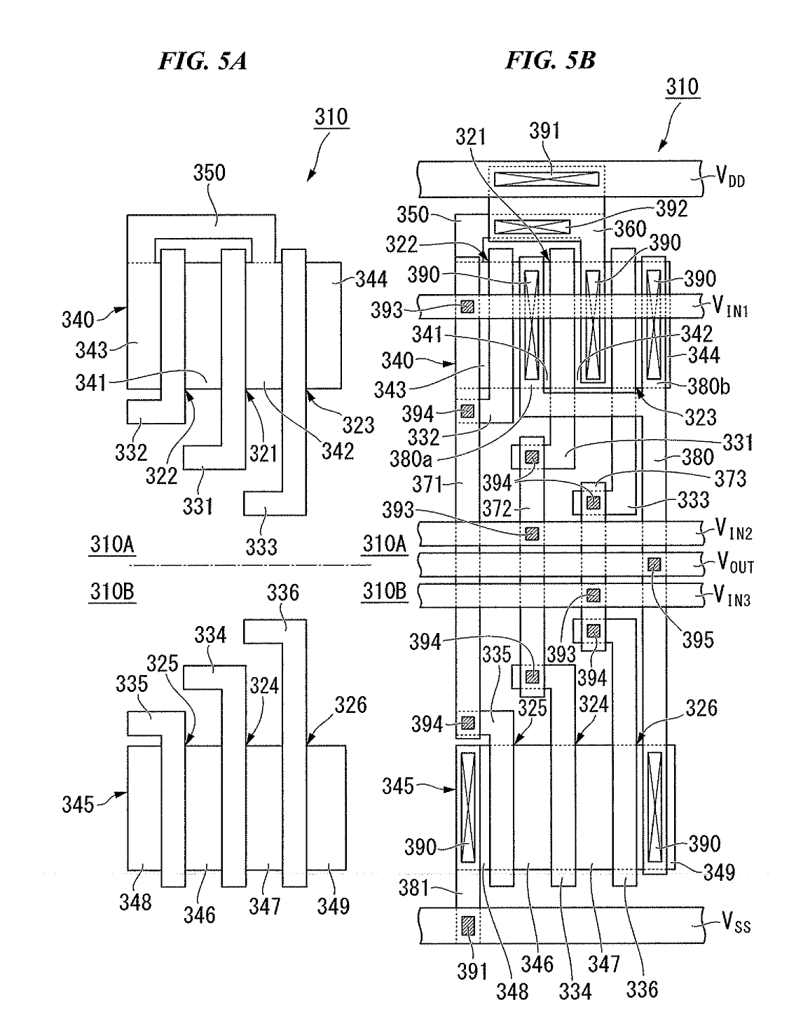

As shown in FIG. 5A, a semiconductor device 310 according to the third embodiment basically includes an N-well region 310A and a P-well region 310B. A p-type semiconductor region 340, three gate wirings 331, 332 and 333 and a diffusion region 350 are provided at the N-well region 310A. The gate wirings 331, 332 and 333 are formed on the p-type semiconductor region 340. The diffusion region 350 is connected to the p-type semiconductor region 340. More specifically, the gate wirings 331, 332 and 333 are provided in parallel with each other on the p-type semiconductor region 340. The gate wirings 331, 332 and 333 divide the p-type semiconductor region 340 into four impurity diffusion regions 341 to 344.

An n-type semiconductor region 345, three gate wirings 334, 335 and 336 are provided at the P-well region 310B. The gate wirings 334, 335 and 336 are formed on the n-type semiconductor region 345. More specifically, the gate wirings 334, 335 and 336 are provided in parallel with each other on the n-type semiconductor region 345. The n-type semiconductor region 345 is divided into four impurity diffusion regions 346 to 349 by the gate wirings 334, 335 and 336.

The diffusion region 350 connects the impurity diffusion region 342 and the impurity diffusion region 343. In addition, the diffusion region 350 is not connected to the impurity diffusion region 341 and the impurity diffusion region 344.

Three p-channel MOSFETs are formed at the N-well region 310A by the p-type semiconductor region 340 and three gate wirings 331, 332 and 333 which are formed on the p-type semiconductor region 340. More specifically, a semiconductor device 310 includes a first transistor 321, a second transistor 322 and a third transistor 323. The first transistor 321 uses the gate wiring 331 as the gate electrode, and uses the impurity diffusion regions 341 and 342 as the source region and the drain region. The second transistor 322 uses the gate wiring 332 as the gate electrode, and uses the impurity diffusion regions 341 and 343 as the source region and the drain region. The third transistor 323 uses the gate wiring 333 as the gate electrode, and uses the impurity diffusion regions 342 and 344 as the source region and the drain region.

On the other hand, three n-channel MOSFETs are formed at the P-well region 310B by the n-type semiconductor region 345 and the three gate wirings 334, 335 and 336 which are formed on the n-type semiconductor region 345. More specifically, the semiconductor device 310 includes a fourth transistor 324, a fifth transistor 325 and a sixth transistor 326. The fourth transistor 324 uses the gate wiring 334 as the gate electrode, and uses the impurity diffusion regions 346 and 347 as the source region and the drain region. The fifth transistor 325 uses the gate wiring 335 as the gate electrode, and uses the impurity diffusion regions 346 and 348 as the source region and the drain region. The sixth transistor 326 uses the gate wiring 336 as the gate electrode, and uses the impurity diffusion regions 347 and 349 as the source region and the drain region.

In the semiconductor device 310, the impurity diffusion region 342 and the impurity diffusion region 343 are connected to each other by the diffusion region 350. The impurity diffusion region 342 is a source region or a drain region of the first transistor 321. The impurity diffusion region 343 is a source region or a drain region of the second transistor 322.

The impurity diffusion region 341 is used as the source region or the drain region of the first transistor 321 or the second transistor 322.

In addition, the impurity diffusion region 342 is used as the source region or the drain region of the first transistor 321 or the third transistor 323.

In the semiconductor device 310, the impurity diffusion region 347 is used as both the source region and the drain region of the fourth transistor 324 and the sixth transistor 326. In addition, the impurity diffusion region 346 is used as both the source region and the drain region of the fourth transistor 324 and the fifth transistor.

For example, the p-type semiconductor layer 340 and the diffusion region 350 are formed by injecting boron into a silicon substrate. On the other hand, the n-type semiconductor layer 345 is formed by injecting phosphorus into the silicon substrate.

A silicide layer may be formed on the surface of the p-type semiconductor layer 340, the diffusion region 350 and the n-type semiconductor layer 345 by using a salicide technology. Especially, if the silicide layer is formed on the diffusion region 350, it is possible to decrease the resistance value of the diffusion region 350.

In the semiconductor device 310 which is includes aforementioned basic configurations, as shown FIG. 5B, plurality of wirings are laminated. More specifically, a first wiring 360, a second wiring 371, a wiring 372, a wiring 373, a wiring 380, and a wiring 381 are laminated on a layer which is provided with the gate wirings 331 to 336. The first wiring 360 is formed on the impurity diffusion region 342. The second wiring 371 is formed above an area which is from the impurity diffusion region 343 to the gate wiring 335. The wiring 372 is formed above an area which is from the gate line 331 to the gate wiring 334. The wiring 373 is formed above an area which is from the gate wiring 333 to the gate wiring 336. The wiring 380 is formed above an area which is from the impurity diffusion region 344 to the impurity diffusion region 349. The wiring 381 is formed above the impurity diffusion region 348.

An input wiring VIN1 (a third wiring), an input wiring VIN2, an input wiring VIN3, an output wiring VOUT, a supply wiring VDD and a supply wiring VSS are laminated above the layer which is provided with the first wiring 360, the second wiring 371 and wirings 372, 373, 380 and 381, via another layer. In addition, the input wiring VIN1, the input wiring VIN2, the input wiring VIN3, the output wiring VOUT, the supply wiring VDD and the supply wiring VSS are provided along a direction which is parallel to the first wiring 360.

The supply wiring VDD is connected to the first wiring 360 via the contact 391. The first wiring 360 is connected to the impurity diffusion region 342 which is the source region of the first transistor 321 via the contact 390. The first wiring 360 is connected to the impurity diffusion region 343 which is the source region of the second transistor 322 via the contact 392 and the diffusion region 350.

The supply wiring VSS is connected to the wiring 381 via the contact 391. The wiring 381 is connected to the impurity diffusion region 348 which is the source region of the fifth transistor 325 via the contact 390.

The input wiring VIN1 (the third wiring) is provided above the first to third transistors 321 to 323 and the second line 371, and is connected to the second wiring 371 via the contact 393. The second wiring 371 is connected to the gate wiring 332 and the gate wiring 335 at the N-well region 310A and the P-well region 310B via the contact 394.

The input line VIN2 is provided above the wiring 372, and is connected to the wiring 372 via the contact 393. The wiring 372 is connected to the gate wiring 331 and the gate wiring 334 at the N-well region 310A and the P-well region 310B via the contact 394.

The input wiring VIN3 is provided above the wiring 373, and is connected to the wiring 373 via the contact 393. The line 373 is connected to the gate wiring 333 and the gate wiring 336 at the N-well region 310A and the P-well region 310B via the contact 394.

The output wiring VOUT is provided above the wiring 380, and is connected to the wiring 380 via the contact 395. The line 380 diverts the line 380a and the wiring 380b at the N-well region 310A. The wiring 380a and the wiring 380b are connected to the impurity diffusion regions 341 and 344. The wiring 380 is connected to the impurity diffusion region 349 at the P-well region 310B via the contact 390.

For example, the first wiring 360, the second wiring 371, wirings 372, 373, 380 and 381, the input wiring VIN1 (the third wiring), the input wiring VIN2, the input wiring VIN3, the output wiring VOUT, the supply wiring VDD and the supply wiring VSS made of one of copper, aluminium, and a metal having a high melting point, and are formed by a general multi level interconnection technology.

As described above, according to the semiconductor device 310 of the third embodiment has the diffusion region 350 which connects the impurity diffusion regions 342 and 343. Therefore, it is possible to obtain the effect similar to the semiconductor device 110 of the first embodiment and the semiconductor device 210 of the second embodiment. Therefore, it is possible to decrease the area in which the wirings are arranged in the chip.

In the semiconductor device 310 of the third embodiment, if plurality of transistors and plurality of wirings are provided as shown in FIG. 5A and FIG. 5B, it is possible to form the NAND gate circuit shown in FIG. 4 easily.

What is claimed is:

1. A semiconductor device comprising:
a first semiconductor diffusion region of a first transistor;
a second semiconductor diffusion region of a second transistor; and
a third semiconductor diffusion region that connects the first and second semiconductor diffusion regions to each other.

2. The semiconductor device according to claim 1, wherein the first semiconductor diffusion region is one of source and drain regions of the first transistor, and the second semiconductor diffusion region is one of source and drain regions of the second transistor.

3. The semiconductor device according to claim 1, further comprising:
a common semiconductor diffusion region that commonly performs as one of source and drain regions of the first transistor and also one of source and drain regions of the second transistor.

4. The semiconductor device according to claim 3, wherein the common semiconductor diffusion region is isolated from the third semiconductor diffusion region.

5. The semiconductor device according to claim 1, further comprising:
a first wiring connected via a contact to at least one of the third semiconductor diffusion region and the first semiconductor diffusion region;
an insulating layer which covers the second semiconductor diffusion region; and
a second wiring extending over the insulating layer, the second line being separated from the second semiconductor diffusion region.

6. The semiconductor device according to claim 5, further comprising:
a third wiring extending over the first and second transistors and the second line, the third wiring crossing over the second line in plan view, a contact that connects the second and third lines to each other at a cross-over position of the second and third lines.

7. The semiconductor device according to claim 1, wherein the third semiconductor diffusion region have the same conductivity type as the first and second semiconductor diffusion regions so that the first, second and third semiconductor diffusion regions have the same potential.

8. A semiconductor device comprising:
a first transistor having a first gate, a first source and a first drain;
a second transistor having a second gate, a second source and a second drain; and
a diffusion region that connects one of the first source and the first drain to one of the second source and the second drain.

9. The semiconductor device according to claim 8, further comprising:
a common semiconductor diffusion region that commonly performs as one of the first source and the first drain and also one of the second source and the second drain.

10. The semiconductor device according to claim 9, wherein the common semiconductor diffusion region is isolated from the diffusion region.

11. The semiconductor device according to claim 8, further comprising:
a first wiring connected via a contact to at least one of the diffusion region and the first source and the first drains;
an insulating layer which covers at least one of the second source and the second drain of the second transistor; and
a second wiring extending over the insulating layer, the second line being separated from the at least one of the second source and second drain of the second transistor.

12. The semiconductor device according to claim 1, further comprising:
a third wiring extending over the first and second transistors and the second wiring, the third wiring crossing over the second wiring, a contact that connects the second and third wirings to each other at a cross-over position of the second and third wirings.

13. A semiconductor device comprising:
a first transistor;
a second transistor; and
a semiconductor diffusion region extends between the first and second transistors, the semiconductor diffusion region extends to reach both one of source and drain regions of the first transistor and one of source and drain regions of the second transistor.

14. The semiconductor device according to claim 13, further comprising:
a common semiconductor diffusion region that commonly performs as one of source and drain regions of the first transistor and also one of source and drain regions of the second transistor.

15. The semiconductor device according to claim 14, wherein the common semiconductor diffusion region is isolated from the semiconductor diffusion region.

16. The semiconductor device according to claim 13, further comprising:
a first wiring connected via a contact to at least one of the semiconductor diffusion region and one of source and drain regions of the first transistor;
an insulating layer which covers at least one of source and drain regions of the second transistor; and
a second wiring extending over the insulating layer, the second wiring being separated from the second transistor.

17. The semiconductor device according to claim 14, further comprising:
a third wiring extending over the first and second transistors and the second wiring, the third wiring crossing over the second wiring, a contact that connects the second and third wirings to each other at a cross-over position of the second and third wirings.
